(19) United States
(12) Patent Application Publication
(10) Pub. No.: US 2006/0145208 A1
(43) Pub. Date: Jul. 6, 2006

(54) Photodiode in CMOS image sensor and method of manufacturing the same

(76) Inventor: Joon Hwang, Cheongju city (KR)

Correspondence Address: Song K. Jung;MCKENNA LONG & ALDRIDGE LLP, 1900 K Street, N.W., Washington, DC, 20006, US

(21) Appl. No.: 11/319,265

(22) Filed: Dec. 29, 2005

(30) Foreign Application Priority Data
Dec. 30, 2004 (KR) 10-2004-0117221

(51) Int. Cl. H01L 31/113

(52) U.S. Cl. 257/292

(57) ABSTRACT

A CMOS image sensor is provided in which a P-type impurity containing layer is formed in a blue photodiode region and a P-type diffusion region is formed by diffusion such that a junction depth is reduced and blue light is efficiently received to improve image quality. A method of manufacturing a CMOS image sensor includes forming a second conductive type diffusion region on a first conductive type semiconductor substrate in a photodiode region, forming a first conductive type impurity containing region formed on the second conductive type diffusion region in the photodiode region, and forming a first conductive type diffusion region by diffusing impurities in the first conductive type impurity containing region into the second conductive type diffusion region.

This application claims the benefit of Korean Patent Application No. 10-2004-0117221, filed on Dec. 30, 2004, which is hereby incorporated by reference for all purposes as if fully set forth herein.

### BACKGROUND OF THE INVENTION

1. Field of the Invention

The present invention relates to CMOS image sensors, and more particularly, to a photodiode in a CMOS image sensor and a method of manufacturing the same, which provides a P-type impurity containing layer in a blue photodiode region and forms a P-type diffusion region by diffusion, to thereby reduce a junction depth. Thus, blue light may be efficiently received to improve image quality.

2. Discussion of the Related Art

An image sensor is a semiconductor device for converting an optical image into an electrical signal, and includes a switching type complementary metal-oxide-silicon (CMOS) image sensor. The CMOS image sensor includes a charge-coupled device in which charge carriers are stored in metal-oxide-silicon (MOS) capacitors which are very close to each other and MOS transistors. The MOS capacitors and the MOS transistors are manufactured with a number of pixels using CMOS technology which uses a control circuit and a signal processing circuit in a peripheral circuit and sequentially detects output using the MOS transistors.

A CMOS image sensor for converting information of a subject into an electrical signal includes signal processing chips having a photodiode. An amplifier, an analog/digital converter, an internal voltage generator, a timing generator, and a digital logic may be connected to one chip, thereby reducing space, power, and cost. The charge coupled device may be manufactured by a special method, while the CMOS image sensor may be manufactured by a method of etching a silicon wafer. This method is cheaper than the method of manufacturing the charge coupled device. Thus, the CMOS image sensor is advantageous in mass production and has an advantageous degree of integration.

Among blue, red, and green light, blue light of a shortest wavelength penetrates a silicon lattice by 0.5 μm or less in the CMOS image sensor. In order to reduce dangling bond in the surface of a semiconductor substrate, a photodiode is formed by a PNP diode having a P⁰/N⁻/P⁻ epitaxial structure. Here, the P⁰ layer is formed by ion injection. This results in a junction depth increase and thus it is difficult to efficiently receive the blue light and convert light energy into electrical energy.

FIG. 1 illustrates a photodiode in a CMOS image sensor according to the related art. As shown in FIG. 1, a low concentration P-type epitaxial layer 111 is grown on a high concentration P-type substrate 110, and a shallow-trench isolation region 118 for isolating elements is formed in the epitaxial layer 111 by forming a trench in the epitaxial layer 111 and filling the trench with an insulating layer. Then, a gate insulating layer 116 is formed on the epitaxial layer 111, and a gate electrode 114 of a transfer transistor and a gate electrode 115 of a reset transistor are formed on the gate insulating layer 116.

A low concentration N-type diffusion region 113 is formed in the epitaxial layer 111 of a photodiode region 120. A high concentration N-type diffusion region 117 is formed between the gate electrode 114 of the transfer transistor and the gate electrode 115 of the reset transistor and in the epitaxial layer 111 at both sides of the gate electrode 115 of the reset transistor. A floating diffusion region 121 is the region between the gate electrode 114 of the transfer transistor and the gate electrode 115 of the reset transistor.

A P-type diffusion region 119 having a concentration lower than that of the epitaxial layer 111 and higher than that of the substrate 110 is formed on the low concentration N-type diffusion region 113 at a thickness of approximately 0.2-0.5 μm to form a photodiode in the photodiode region 120.

Thus, a blue photodiode of the CMOS image sensor is formed by the P-type semiconductor substrate 110, the N-type diffusion region 113, and the P-type diffusion region 119. The junction depth of the P-type diffusion region 119, which is formed on the N-type diffusion region 113 by ion injection, is increased. Thus, it is difficult to efficiently receive the blue light and convert the light energy into electrical energy.

### SUMMARY OF THE INVENTION

Accordingly, the present invention is directed to a photodiode in a CMOS image sensor and a method of manufacturing the same that substantially obviates one or more of the problems due to limitations and disadvantages of the related art.

An advantage of the present invention is to provide a photodiode in a CMOS image sensor and a method of manufacturing the same, in which a P-type impurity containing layer is formed in a blue photodiode region and a P-type diffusion region is formed by diffusion such that a junction depth is reduced and blue light is efficiently received to thereby improve image quality.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the present invention, as embodied and broadly described, there is provided a photodiode in a CMOS image sensor comprising a first conductive type semiconductor substrate, a second conductive type diffusion region formed on the semiconductor substrate in a photodiode region, a first conductive type diffusion region formed on the second conductive type diffusion region in the photodiode region, and a first conductive type impurity containing layer formed on the first conductive type diffusion region.

In another aspect of the present invention, there is provided a method of manufacturing a photodiode in a CMOS image sensor comprising providing a first conductive type semiconductor substrate, forming a second conductive type diffusion region on the semiconductor substrate in a photodiode region, forming a first conductive type impurity containing region on the second conductive type diffusion region in the photodiode region, and forming a first conductive type diffusion region by diffusing impurities in the first conductive type impurity containing region into the second conductive type diffusion region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a cross-sectional view of a photodiode in a CMOS image sensor according to the related art; and

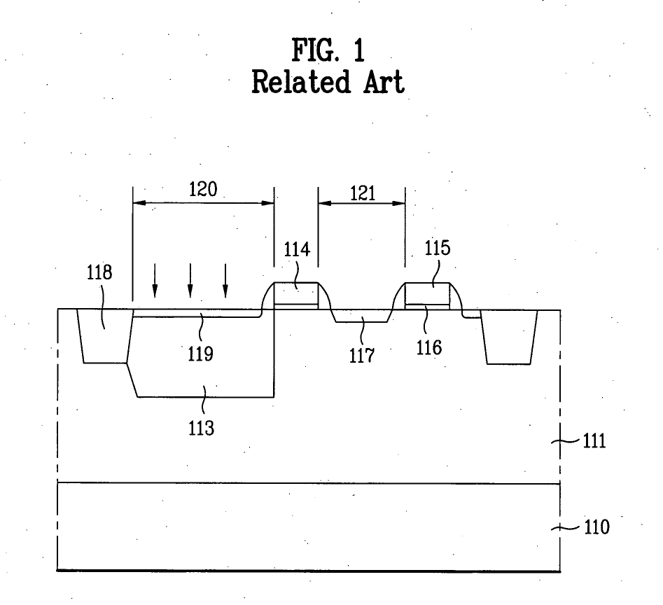

FIG. 2 is a cross-sectional view of a photodiode in a CMOS image sensor according to the present invention.

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

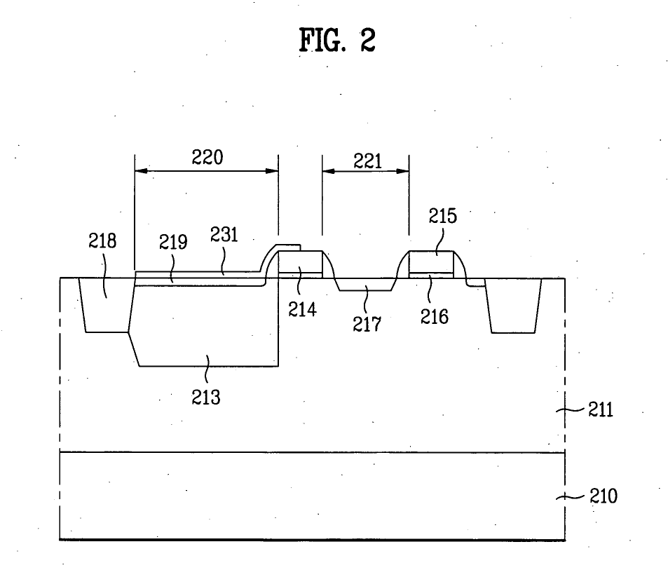

FIG. 2 illustrates a photodiode in a CMOS image sensor according to the present invention. As shown in FIG. 2, a photodiode region 220 and a floating diffusion region 221 are defined. A low concentration P-type epitaxial layer 211 is grown on a high concentration P-type substrate 210. A shallow-trench isolation region 218 for isolating elements is formed by forming a trench in the epitaxial layer 211 and filling the trench with an insulating layer. The floating diffusion region 221 is the region between a gate electrode 214 of a transfer transistor and a gate electrode 215 of a reset transistor.

A gate insulating layer 216 is formed on the epitaxial layer 211. The gate electrode 214 of the transfer transistor and the gate electrode 215 of the reset transistor are formed on the gate insulating layer 216. A low concentration N-type diffusion region 213 is formed in the epitaxial layer 211 in a photodiode region 220. A high concentration N-type diffusion region 217 is formed between the gate electrode 214 of the transfer transistor and the gate electrode 215 of the reset transistor and in the epitaxial layer 211 at both sides of the gate electrode 215 of the reset transistor.

A boron silicate glass (BSG) layer 231 containing boron which is a P-type impurity may be laminated on the epitaxial layer 211. The BSG layer 231 may be coated with photoresist, which is exposed and developed to form a photoresist pattern (not shown) in the photodiode region 220. The BSG layer 231 is selectively etched using the photoresist pattern as a mask such that the BSG layer 231 remains in the photodiode region 220, thereby forming a BSG layer pattern 231. After the photoresist pattern is removed, the boron contained in the BSG layer pattern 231 is diffused into the epitaxial layer 211 by a heating process to form a P-type diffusion region 219. The junction depth of the P-type diffusion region 219 is approximately 0.1-0.2 μm.

According to the present invention, since a P-type diffusion region formed on an N-type diffusion region is formed by a diffusion method using an impurity containing layer instead of ion injection, a decreased and small junction depth may be realized. Thus, a photoelectric effect of blue light having a relatively short wavelength may be efficiently obtained in an image sensor. Therefore, image reproducibility may be improved by a blue tone.

It will be apparent to those skilled in the art that various modifications and variation can be made in the present invention without departing from the spirit or scope of the invention. Thus, it is intended that the present invention cover the modifications and variations of the invention provided they come within the scope of the appended claims and their equivalents.

What is claimed is:

1. A photodiode in a CMOS image sensor, comprising:
a first conductive type semiconductor substrate;
a second conductive type diffusion region formed on the semiconductor substrate in a photodiode region;
a first conductive type diffusion region formed on the second conductive type diffusion region in the photodiode region; and
a first conductive type impurity containing layer formed on the first conductive type diffusion region.

2. The photodiode according to claim 1, wherein the first conductive type impurity containing layer is a boron silicate glass layer.

3. The photodiode according to claim 1, wherein the first conductive type diffusion region is a P-type region.

4. The photodiode according to claim 1, wherein the first conductive type diffusion region has a junction depth of approximately 0.1-0.2 μm.

5. A method of manufacturing a photodiode in a CMOS image sensor, comprising:
providing a first conductive type semiconductor substrate;
forming a second conductive type diffusion region on the semiconductor substrate in a photodiode region;
forming a first conductive type impurity containing region on the second conductive type diffusion region in the photodiode region; and
forming a first conductive type diffusion region by diffusing impurities in the first conductive type impurity containing region into the second conductive type diffusion region.

6. The method according to claim 5, wherein the forming of the first conductive type diffusion region comprises:
forming a first conductive type impurity containing layer on the semiconductor substrate;
selectively etching the first conductive type impurity containing layer such that the first conductive type impurity containing layer remains in the photodiode region; and
thermally diffusing impurities of the first conductive type impurity containing layer to form the first conductive type diffusion region.

7. The method according to claim 5, wherein the first conductive type impurity containing region is a boron silicate glass region.

8. The method according to claim 5, wherein the first conductive type diffusion region is a P-type region.

9. The method according to claim 5, wherein the first conductive type diffusion region has a junction depth of approximately 0.1-0.2 μm.
